(19) United States
(12) Patent Application Publication
(10) Pub. No.: US 2012/0058625 A1
(43) Pub. Date: Mar. 8, 2012

(54) FILM FOR SEMICONDUCTOR DEVICE, AND SEMICONDUCTOR DEVICE

(76) Inventors: Yasuhiro AMANO, Ibaraki-shi (JP); Miki MORITA, Ibaraki-shi (JP)

(21) Appl. No.: 13/224,554

(22) Filed: Sep. 2, 2011

(30) Foreign Application Priority Data
Sep. 6, 2010 (JP) 2010-199021

(51) Int. Cl. B32B 3/02; B32B 27/00; H01L 21/78; B32B 9/04

(52) U.S. Cl. 438/464; 428/411.1; 428/500; 428/64.1; 257/E21.599

(57) ABSTRACT

The present invention provides a film for a semiconductor device that is capable of suppressing the generation of a transfer mark on an adhesive film when a film for a semiconductor device, in which an adhesive film with a dicing sheet obtained by laminating an adhesive film onto a dicing film is laminated onto a cover film leaving a prescribed spacing, is wound up into a roll. It is a film for a semiconductor device in which an adhesive film with a dicing sheet obtained by laminating an adhesive film onto a dicing film is laminated onto a cover film leaving a prescribed spacing, wherein a ratio Ea/Eb of the tensile storage modulus Ea of the adhesive film at 23° C. to the tensile storage modulus Eb of the cover film at 23° C. is in a range of 0.001 to 50.

### BACKGROUND OF THE INVENTION

1. Field of the Invention

The present invention relates to a film for a semiconductor device and a semiconductor device manufactured using the film for a semiconductor device.

2. Description of the Related Art

Conventionally, silver paste has been used to bond a semiconductor chip to a lead frame or an electrode member in the step of producing a semiconductor device. The treatment for the sticking is conducted by coating a paste-form adhesive on a die pad of a lead frame, or the like, mounting a semiconductor chip on the die pad, and then setting the paste-form adhesive layer.

However, about the paste-form adhesive, the amount of the coated adhesive, the shape of the coated adhesive, and on the like are largely varied in accordance with the viscosity behavior thereof, a deterioration thereof, and on the like. As a result, the thickness of the formed paste-form adhesive layer becomes uneven so that the reliability in strength of bonding a semiconductor chip is poor. In other words, if the amount of the paste-form adhesive coated on an electrode member is insufficient, the bonding strength between the electrode member and a semiconductor chip becomes low so that in a subsequent wire bonding step, the semiconductor chip is peeled. On the other hand, if the amount of the coated paste-form adhesive is too large, this adhesive flows out to stretch over the semiconductor chip so that the characteristic becomes poor. Thus, the yield or the reliability lowers. Such problems about the adhesion treatment become particularly remarkable with an increase in the size of semiconductor chips. It is therefore necessary to control the amount of the coated paste-form adhesive frequently. Thus, the workability or the productivity is deteriorated.

In this coating step of a paste-form adhesive, there is a method of coating the adhesive onto a lead frame or a forming chip by an independent operation. In this method, however, it is difficult to make the paste-form adhesive layer even. Moreover, an especial machine or a long time is required to coat the paste-form adhesive. Thus, an adhesive film with a dicing sheet which makes a semiconductor wafer to be bonded and held in a dicing step and further gives an adhesive layer, for bonding a chip, which is necessary for amounting step is disclosed (see, for example, JP-A-60-57342).

This adhesive film with a dicing sheet has a structure wherein an adhesive layer and an adhesive layer are successively laminated on a supporting substrate. That is, a semiconductor wafer is diced in the state that the wafer is held on the adhesive layer, and then the supporting substrate is extended; the chipped works are peeled together with the adhesive layer; the peeled works are individually collected; and further the chipped works are bonded onto an adherend such as a lead frame through the adhesive layer.

Due to limitations in the manufacturing process, an adhesive film with a dicing sheet is conventionally produced by fabricating a dicing film and an adhesive film separately and then pasting both films together. Because of this, the adhesive film with a dicing sheet is manufactured by applying a tensile force onto each film when the film is transported by a roller from the viewpoint of preventing generation of sagging, winding deviation, positional deviation, voids (air bubbles), etc. in the manufacturing process of the film.

There is a case where the adhesive film with a dicing sheet of this type hardens when it is kept under a high temperature and high humidity environment or when it is stored for a long period of time under a condition in which a load is applied. As a result, such a case leads to an increase of fluidity of the adhesive layer, a decrease of holding power to a semiconductor wafer, and deterioration of a peeling property after dicing. Because of this, the adhesive film with a dicing sheet is often transported while being kept in a frozen condition of −30 to −10° C. or a refrigerated condition of −5 to 10° C., and accordingly, film characteristics can be maintained for a long period of time.

As the adhesive film with a dicing sheet described above, there is an adhesive film with a dicing sheet on which a pre-cut processing is performed in which the film is processed in advance into the shape of a semiconductor wafer to which the film is to be applied (e.g. a circular shape), considering the workability of pasting the film onto a semiconductor wafer, pasting the film to a ring frame in dicing, etc.

Such an adhesive film with a dicing sheet is manufactured by pasting the adhesive film punched into a circular shape onto a dicing film obtained by laminating a pressure-sensitive adhesive layer onto a base and then punching the dicing film into a circular shape that corresponds to a ring frame. With this process, the ring frame can be pasted to the outer periphery of the dicing film and the adhesive film with a dicing sheet can be fixed when the semiconductor wafer is diced.

The adhesive film with a dicing sheet on which the pre-cut processing was performed is pasted onto a long cover film leaving a prescribed spacing, wound into a roll, and transported and stored as a film for a semiconductor device.

### SUMMARY OF THE INVENTION

However, in the case of the above-described film for a semiconductor device, the thickness of the portion where the adhesive film with a dicing sheet is laminated becomes larger than the thickness of the portion where the adhesive film is not laminated. Because of this, especially when the number of winding is large or the tension during winding up is high, there is a case where an edge of an adhesive film with a dicing sheet is pressed against another adhesive film with a dicing sheet, a rolling mark is transferred, and flatness of the adhesive film is lost. Such a transfer mark occurs noticeably especially when the adhesive film is formed with a relatively soft resin, when the thickness of the adhesive film is large, when the number of windings of the film for a semiconductor device is large, etc. Then, voids (air bubbles) are generated between the semiconductor wafer and the adhesive film when the adhesive film having such a transfer mark and lacking flatness is pasted onto a semiconductor wafer. Such voids cause defects during the semiconductor wafer processing, and there is a possibility that the yield of the semiconductor device manufactured decreases.

In order to suppress the generation of the transfer mark, a method is considered of lowering the winding pressure of the film for a semiconductor device. However, winding deviation occurs with this method and there is a possibility that difficulties occur during practical use, such as a difficulty in setting the film to a tape mounter.

The present invention has been made in view of the above-described problems, and an object thereof is to provide a film for a semiconductor device that is capable of suppressing the generation of the transfer mark on the adhesive film when a film for a semiconductor device in which an adhesive film with a dicing sheet obtained by laminating an adhesive film onto a dicing film is laminated onto a cover film leaving a prescribed spacing is wound up into a roll.

The present inventors investigated a film for a semiconductor device to solve the above-mentioned conventional problems. As a result, it was found that generation of the transfer mark on a die bond film can be prevented by controlling the tensile storage modulus of an adhesive film that constitutes the film for a semiconductor device and the tensile storage modulus of a cover film, and the present invention was completed.

That is, the film for a semiconductor device according to the present invention is a film for a semiconductor device in which an adhesive film with a dicing sheet obtained by laminating an adhesive film onto a dicing film is laminated onto a cover film leaving a prescribed spacing and is characterized in that the ratio Ea/Eb of the tensile storage modulus Ea of the adhesive film at 23° C. to the tensile storage modulus Eb of the cover film at 23° C. is in a range of 0.001 to 50.

The larger the value of Ea/Eb is, relatively the harder the adhesive film is and the softer the cover film is. On the other hand, the smaller the value of Ea/Eb is, relatively the softer the adhesive film is and the harder the cover film is. According to the above-described configuration, because Ea/Eb is 0.001 or more, the hardness (the tensile storage modulus Ea) of the adhesive film comes not to fall below a certain level. Therefore, generation of the transfer mark on the adhesive film that constitutes the adhesive film with a dicing sheet can be suppressed. Further, because Ea/Eb is 0.001 or more and the hardness (the tensile storage modulus Ea) of the adhesive film comes not to fall below a certain level, the slip property of the adhesive film is improved and the generation of wrinkles when the adhesive film is pasted onto the cover film can be suppressed.

Further, because Ea/Eb is 50 or less, the hardness (the tensile storage modulus Eb) of the cover film comes not to fall below a certain level. On the other hand, the hardness (the tensile storage modulus Ea) of the adhesive film comes not to exceed a certain level. Therefore, the follow-up property of the cover film to the adhesive film can be improved. Further, generation of creases on the cover film when the adhesive film is pasted to the cover film can be suppressed, the damage of the adhesive film can be prevented, and entry of air bubbles in between the films can be prevented. As a result, floating of the cover film and generation of voids between the adhesive film and the semiconductor wafer when mounting the semiconductor wafer can be suppressed.

According to the above-described configuration, generation of the transfer mark on the adhesive film when the film is wound up into a roll can be suppressed. Further, film floating of the cover film and generation of voids (air bubbles) between the adhesive film and the semiconductor wafer when mounting the semiconductor wafer can be suppressed.

In the above-described configuration, a peeling force F₁ between the adhesive film and the cover film obtained by a T type peeling test under conditions of a temperature of 23±2° C. and a peeling rate of 300 mm/min is in a range of 0.025 to 0.075 N/100 mm, a peeling force F₂ between the adhesive film and the dicing film is in a range of 0.08 to 10 N/100 mm, and F₁ and F₂ preferably satisfy a relationship of F₁<F₂.

A film for a semiconductor device is manufactured while applying a tensile force to a dicing film, an adhesive film, and a cover film from the viewpoint of preventing sagging, displacement of winding, positional shift, voids (air bubbles), and the like from occurring. As a result, the film for a semiconductor device is manufactured in a state that tensile residual strain exists in any of the films that constitute the film. This tensile residual strain causes shrinking of each film when it is transported or stored for a long time in a frozen condition of −30 to −10° C. or a low temperature condition of −5 to 10° C., for example. Further, the degree of shrinking differs because physical properties of the films differ. For example, the dicing film has the largest degree of shrinking among the films, and the cover film has the smallest degree of shrinking. As a result, interface delamination between the dicing film and the adhesive film is generated, and the film lifting phenomenon of the cover film is brought about.

A configuration that satisfies the relationship of F₁<F₂ is adopted in the above-described configuration under the condition that the peel force F₁ between the adhesive film and the cover film is within a range of 0.025 to 0.075 N/100 mm and the peel force F₂ between the adhesive film and the dicing film is within a range of 0.08 to 10 N/100 mm. As described above, shrinking of the dicing film is the largest among the films. Therefore, by making the peel force F₂ between the adhesive film and the dicing film larger than the peel force F₁ between the adhesive film and the cover film, shrinking of the dicing film having the largest shrinking rate is suppressed and the interface delamination between the dicing film and the adhesive film and the film lifting phenomenon of the cover film are prevented. Further, part or the entirety of the adhesive film can be prevented from being transferred onto the cover film.

In the above-described configuration, the adhesive film preferably contains a thermoplastic resin having a weight average molecular weight of 300,000 or more and 1,500,000 or less. By making the weight average molecular weight of the thermoplastic resin 300,000 or more, the tensile storage modulus Ea of the adhesive film at 23° C. can be controlled to a preferred value.

In the above-described configuration, the adhesive film preferably contains a thermoplastic resin in which monomer components having a carboxyl group-containing monomer are polymerized. By incorporating a thermoplastic resin in which monomer components having a carboxyl group-containing monomer are polymerized, the tensile storage modulus Ea of the adhesive film can be controlled to a preferred value.

In the above-described configuration, the adhesive film preferably contains an acrylic resin as a thermoplastic resin, and the glass transition temperature of the acrylic resin is preferably 20° C. or less. When the glass transition temperature of the acrylic resin contained in the adhesive film is 20° C. or less, a decrease in the fluidity of the adhesive film can be prevented. Further, good tackiness to a semiconductor wafer can be maintained.

In the above-described configuration, the tensile storage modulus Ea of the adhesive film at 23° C. is preferably 5 to 5000 MPa.

In the above-described configuration, the tensile storage modulus Eb of the cover film at 23° C. is preferably 5 to 5000 MPa.

Further, the semiconductor device according to the present invention is manufactured using the film for a semiconductor device described above.

### BRIEF DESCRIPTION OF THE DRAWINGS

FIG. 1A is a plan view showing an outline of the film for a semiconductor device according to the present embodiment and FIG. 1B is a partial cross-sectional view thereof;

FIG. 2 is a partial cross-sectional view of the film for a semiconductor device shown in FIGS. 1A and 1B in a state of a roll; and

FIGS. 3A to 3C are schematic views for explaining the manufacturing process of the film for a semiconductor device.

### DESCRIPTION OF THE REFERENCE NUMERALS

1 adhesive film with a dicing sheet
2 cover film
10 film for a semiconductor device
11 dicing film
12 adhesive film
13 base
14 pressure-sensitive adhesive layer
21 first separator
22 base separator
23 second separator

### DESCRIPTION OF THE PREFERRED EMBODIMENT

The film for a semiconductor device according to the present embodiment is explained below.

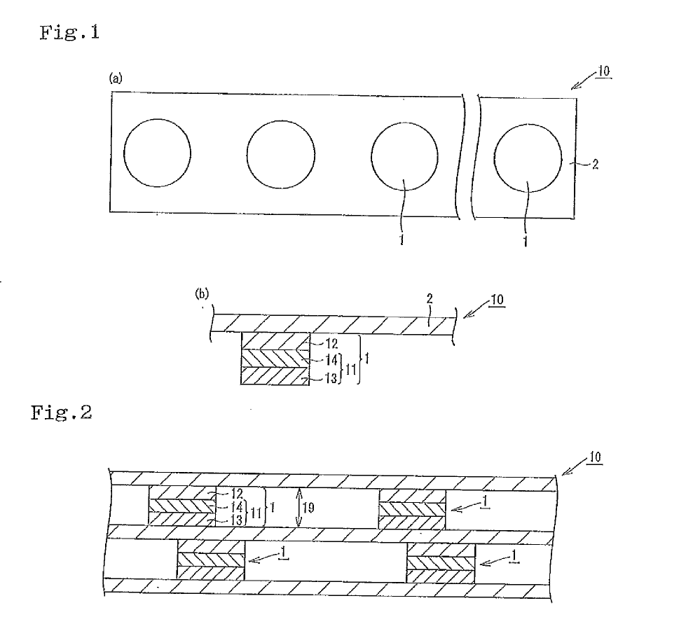

FIG. 1A is a plan view showing an outline of the film for a semiconductor device according to the present embodiment, and FIG. 1B is a partial cross-sectional view thereof. A film 10 for a semiconductor device has a configuration in which adhesive films 1 with dicing sheets are laminated onto a cover film 2 leaving a prescribed spacing. In the adhesive film 1 with a dicing sheet, an adhesive film 12 is laminated onto a dicing film 11, and the dicing film 11 has a structure in which a pressure-sensitive adhesive layer 14 is laminated onto a base 13.

FIG. 2 is a partial cross-sectional view of the film for a semiconductor device shown in FIGS. 1A and 1B in a state of a roll. As shown in FIG. 2, there is a difference in level 19 between the portion where the adhesive film 1 with a dicing sheet is laminated and a portion where the adhesive film 1 with a dicing sheet is not laminated. Further, a plurality of the adhesive films 1 with dicing sheets are laminated on the cover film 2 as shifted in position from each other in a transverse direction. Because of that, the edge of the adhesive film 1 with a dicing sheet is pressed against another adhesive film 1 with a dicing sheet.

In the film 10 for a semiconductor device, the ratio Ea/Eb of the tensile storage modulus Ea of the adhesive film 12 at 23° C. to the tensile storage modulus Eb of the cover film 2 at 23° C. is in a range of 0.01 to 50. Ea/Eb is preferably 0.01 to 30, and more preferably 0.1 to 10. The larger the value of Ea/Eb is, relatively the harder the adhesive film 12 is and the softer the cover film 2 is. On the other hand, the smaller the value of Ea/Eb is, relatively the softer the adhesive film 12 is and the harder the cover film 2 is. With the film 10 for a semiconductor device, because Ea/Eb is 0.001 or more, the hardness (the tensile storage modulus Ea) of the adhesive film 12 comes not to fall below a certain level. Therefore, generation of the transfer mark on the adhesive film 12 that constitutes the adhesive film 1 with a dicing sheet can be suppressed. Further, with the film 10 for a semiconductor device, because Ea/Eb is 0.001 or more and the hardness (the tensile storage modulus Ea) of the adhesive film 12 comes not to fall below a certain level, the slip property of the adhesive film 12 is improved and generation of wrinkles when the adhesive film 12 is pasted onto the cover film 2 can be suppressed.

Further, with the film 10 for a semiconductor device, because Ea/Eb is 50 or less, the hardness (the tensile storage modulus Eb) of the cover film 2 comes not to fall below a certain level. On the other hand, the hardness (the tensile storage modulus Ea) of the adhesive film 12 comes not to exceed a certain level. Therefore, the follow-up property of the cover film 2 to the adhesive film 12 can be improved. Further, generation of creases on the cover film 2 when the adhesive film 12 is pasted to the cover film 2 can be suppressed, damage to the adhesive film 12 can be prevented, and entry of air bubbles in between the films can be prevented. As a result, floating of the cover film 2 and generation of voids between the adhesive film 12 and the semiconductor wafer when mounting the semiconductor wafer can be suppressed.

With the film 10 for a semiconductor device, generation of the transfer mark on the adhesive film 12 when the film is wound up into a roll can be suppressed. Further, floating of the cover film 2 and generation of voids (air bubbles) between the adhesive film 12 and the semiconductor wafer when mounting the semiconductor wafer can be suppressed.

The peeling force F₁ between the adhesive film 12 and the cover film 2 is smaller than the peeling force F₂ between the adhesive film 12 and the dicing film 11. The film 10 for a semiconductor device is manufactured by laminating while applying a tensile force to the dicing film 11, the adhesive film 12, and the cover film 2 from the viewpoint of preventing generation of sagging, winding deviation, positional deviation, voids (air bubbles), etc. in its manufacturing process. Because of that, tensile residual distortion exists in each film. The tensile residual distortion induces shrinking of each film when the film is transported or kept for a long period of time in a frozen condition of −30 to −10° C. or a low-temperature condition of −5 to 10° C., for example. The degree of shrinking is largest in the dicing film, and the degree of shrinking is smallest in the cover film, for example. In the film for a semiconductor device according to the present embodiment, interface peeling between the films and a film floating phenomenon of the cover film 2 caused by a difference of shrinking in films can be prevented by making the relationship between the peeling forces F₁ and F₂ be F₁<F₂. Further, transfer of a part or the whole of the adhesive film 12 onto the cover film 2 can be prevented.

The peeling force F₁ between the adhesive film 12 and the cover film 2 is preferably in a range of 0.025 to 0.075 N/100 mm, more preferably in a range of 0.03 to 0.06 N/100 mm, and especially preferably in a range of 0.035 to 0.05 N/100 mm. When the peeling force F₁ is less than 0.025 N/100 mm, each of the adhesive film 12 and the cover film 2 shrinks at a different shrinkage ratio and the film floating phenomenon of the cover film 2 may occur when the film is transported or kept for a long period of time in a frozen condition of −30 to −10° C. or a low-temperature condition of −5 to 10° C., for example. Further, wrinkles, winding deviation, and contamination by foreign objects may occur during transportation of the film 10 for a semiconductor device. Further, voids (air bubbles) may be generated between the adhesive film 12 and the semiconductor wafer when mounting onto the semiconductor wafer. On the other hand, when the peeling force F₁ is larger than 0.075 N/100 mm, adhesion between the adhesive film 12 and the cover film 2 is too strong, and therefore, there is a case where an adhesive (described in detail later) that constitutes the adhesive film 12 is transferred onto a part of or the entire surface during peeling and shrinking of the cover film 2. When the adhesive film 12 is of a thermosetting type, the value of the peeling force F₁ means a peeling force between the adhesive film 12 before thermal curing and the cover film 2.

The peeling force F₂ between the adhesive film 12 and the dicing film 11 is preferably in a range of 0.08 to 10 N/100 mm, more preferably in a range of 0.1 to 6 N/100 mm, and especially preferably in a range of 0.15 to 0.4 N/100 mm. When the peeling force F₂ is 0.08 N/100 mm or more, each of the dicing film 11 and the adhesive film 12 shrinks at a different shrinkage ratio and interface peeling between the dicing film 11 and the adhesive film 12 can be prevented when the film is transported or kept for a long period of time in a frozen condition of −30 to −10° C. or a low-temperature condition of −5 to 10° C., for example. Further, generation of wrinkles, winding deviation, contamination by foreign objects, and voids can be prevented during transportation of the film 10 for a semiconductor device, etc. Further, generation of chip fly and chipping can be prevented when dicing the semiconductor wafer. On the other hand, when the peeling force F₂ is 10 N/100 mm or less, a good peeling property can be obtained between the adhesive film 12 and the pressure-sensitive adhesive layer 14 when picking up a semiconductor chip, and good pickup of the semiconductor chip can be obtained. Further, attachment of the adhesive (described in detail later) that constitutes the pressure-sensitive adhesive layer 14 onto the semiconductor chip with the adhesive can be prevented. The range of the peeling force F₂ includes the case where the pressure-sensitive adhesive layer in the dicing film 11 is of an ultraviolet-ray curing-type and is cured to a certain degree by ultraviolet radiation in advance. Further, the curing of the pressure-sensitive adhesive layer by ultraviolet radiation may be performed before or after pasting to the adhesive film 12.

The values of the peeling forces F₁ and F₂ are measured according to a T type peeling test (JIS K6854-3) under conditions of a temperature of 23±2° C., a peeling rate of 300 mm/min, and a distance between chucks of 100 mm. The tensile tester used is “Autograph AGS-H” manufactured by Shimadzu Corporation.

The base 13 in the dicing film 11 is a base body for strength of not only the dicing film 11 but also the film 10 for a semiconductor device. Examples there of include polyolefin such as low-density polyethylene, straight chain polyethylene, intermediate-density polyethylene, high-density polyethylene, very low-density polyethylene, random copolymer polypropylene, block copolymer polypropylene, homopolypropylene, polybutene, and polymethylpentene; an ethylene-vinylacetate copolymer; an ionomer resin; an ethylene(meth)acrylic acid copolymer; an ethylene(meth)acrylic acid ester (random or alternating) copolymer; an ethylene-butene copolymer; an ethylene-hexene copolymer; polyurethane; polyester such as polyethyleneterephthalate and polyethylenenaphthalate; polycarbonate; polyetheretherketone; polyimide; polyetherimide; polyamide; whole aromatic polyamides; polyphenylsulfide; aramid (paper); glass; glass cloth; a fluorine resin; polyvinyl chloride; polyvinylidene chloride; a cellulose resin; a silicone resin; metal (foil); and paper. When the pressure-sensitive adhesive layer 14 is of an ultraviolet-ray curing-type, the base 13 preferably has transparency to an ultraviolet ray among the materials exemplified above.

Further, the material of the base material 13 includes a polymer such as a cross-linked body of the above resins. The above plastic film may be also used unstreched, or may be also used on which a monoaxial or a biaxial stretching treatment is performed depending on necessity. According to resin sheets in which heat shrinkable properties are given by the stretching treatment, etc., the adhesive area of the pressure-sensitive adhesive layer 14 and the adhesive film 12 is reduced by thermally shrinking the base material 13 after dicing, and the recovery of the semiconductor chips (a semiconductor element) can be facilitated.

A known surface treatment such as a chemical or physical treatment such as a chromate treatment, ozone exposure, flame exposure, high voltage electric exposure, and an ionized ultraviolet treatment, and a coating treatment by an undercoating agent (for example, a tacky substance described later) can be performed on the surface of the base material 13 in order to improve adhesiveness, holding properties, etc. with the adjacent layer.

The same type or different type of base material can be appropriately selected and used as the base material 13, and a base material in which a plurality of types are blended can be used depending on necessity. Further, a vapor-deposited layer of a conductive substance composed of a metal, an alloy, an oxide thereof, etc. and having a thickness of about 30 to 500 angstrom can be provided on the base material 13 in order to give an antistatic function to the base material 13. The base material 13 may be a single layer or a multi layer of two or more types.

The thickness of the base 13 can be set appropriately without special limitation. However, it is about 5 to 200 μm, for example. The thickness is not especially limited as long as it is a thickness that can withstand the tension by the adhesive film 12 due to the heat shrinkage.

The pressure-sensitive adhesive that is used for forming the pressure-sensitive adhesive layer 14 is not especially limited, and general pressure-sensitive adhesives such as an acrylic pressure-sensitive adhesive and a rubber pressure-sensitive adhesive can be used, for example. The pressure-sensitive adhesive is preferably an acrylic pressure-sensitive adhesive containing an acrylic polymer as a base polymer in view of clean washing of electronic components such as a semiconductor wafer and glass, which are easily damaged by contamination, with ultrapure water or an organic solvent such as alcohol.

Specific examples of the acryl polymers include an acryl polymer in which acrylate is used as a main monomer component. Examples of the acrylate include alkyl acrylate (for example, a straight chain or branched chain alkyl ester having 1 to 30 carbon atoms, and particularly 4 to 18 carbon atoms in the alkyl group such as methylester, ethylester, propylester, isopropylester, butylester, isobutylester, sec-butylester, t-butylester, pentylester, isopentylester, hexylester, heptylester, octylester, 2-ethylhexylester, isooctylester, nonylester, decylester, isodecylester, undecylester, dodecylester, tridecylester, tetradecylester, hexadecylester, octadecylester, and eicosylester) and cycloalkyl acrylate (for example, cyclopentylester, cyclohexylester, etc.). These monomers may be used alone or two or more types may be used in combination. All of the words including “(meth)” in connection with the present invention have an equivalent meaning.

The acrylic polymer may optionally contain a unit corresponding to a different monomer component copolymerizable with the above-mentioned alkyl ester of (meth)acrylic acid or cycloalkyl ester thereof in order to improve the cohesive force, heat resistance or some other property of the polymer. Examples of such a monomer component include carboxyl-containing monomers such as acrylic acid, methacrylic acid, carboxyethyl (meth)acrylate, carboxypentyl (meth)acrylate, itaconic acid, maleic acid, fumaric acid, and crotonic acid; acid anhydride monomers such as maleic anhydride, and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxylmethylcyclohexyl)methyl (meth)acrylate; sulfonic acid group containing monomers such as styrenesulfonic acid, allylsulfonic acid, 2-(meth)acrylamide-2-methylpropanesulfonic acid, (meth) acrylamidepropanesulfonic acid, sulfopropyl (meth)acrylate, and (meth)acryloyloxynaphthalenesulfonic acid; phosphoric acid group containing monomers such as 2-hydroxyethylacryloyl phosphate; acrylamide; and acrylonitrile. These copolymerizable monomer components may be used alone or in combination of two or more thereof. The amount of the copolymerizable monomer (s) to be used is preferably 40% or less by weight of all the monomer components.

For crosslinking, the acrylic polymer can also contain multifunctional monomers if necessary as the copolymerizable monomer component. Such multifunctional monomers include hexane diol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylol propane tri(meth)acrylate, pentaerythritol tri(meth)acrylate, dipentaerythritol hexa(meth)acrylate, epoxy (meth)acrylate, polyester (meth)acrylate, urethane (meth)acrylate etc. These multifunctional monomers can also be used as a mixture of one or more thereof. From the viewpoint of adhesiveness etc., the use amount of the multifunctional monomer is preferably 30 wt % or less based on the whole monomer components.

Preparation of the above acryl polymer can be performed by applying an appropriate manner such as a solution polymerization manner, an emulsion polymerization manner, a bulk polymerization manner, and a suspension polymerization manner to a mixture of one or two or more kinds of component monomers for example. Since the pressure-sensitive adhesive layer preferably has a composition in which the content of low molecular weight materials is suppressed from the viewpoint of prevention of wafer contamination, and since those in which an acryl polymer having a weight average molecular weight of 300000 or more, particularly 400000 to 15000000 is as a main component are preferable from such viewpoint, the pressure-sensitive adhesive can be made to be an appropriate cross-linking type with an internal cross-linking manner, an external cross-linking manner, etc.

To increase the number-average molecular weight of the base polymer such as acrylic polymer etc., an external crosslinking agent can be suitably adopted in the pressure-sensitive adhesive. The external crosslinking method is specifically a reaction method that involves adding and reacting a crosslinking agent such as a polyisocyanate compound, epoxy compound, aziridine compound, melamine crosslinking agent, urea resin, anhydrous compound, polyamine, carboxyl group-containing polymer. When the external crosslinking agent is used, the amount of the crosslinking agent to be used is determined suitably depending on balance with the base polymer to be crosslinked and applications thereof as the pressure-sensitive adhesive. Generally, the crosslinking agent is preferably incorporated in an amount of about 5 parts by weight or less based on 100 parts by weight of the base polymer. The lower limit of the crosslinking agent is preferably 0.1 parts by weight or more. The pressure-sensitive adhesive may be blended not only with the components described above but also with a wide variety of conventionally known additives such as a tackifier, and aging inhibitor, if necessary.

The pressure-sensitive adhesive layer 14 can be formed with an ultraviolet-ray curing-type pressure-sensitive adhesive. The adhesive power of the ultraviolet-ray curing-type pressure-sensitive adhesive can be easily lowered by increasing the degree of crosslinking by ultraviolet ray radiation, and a difference in the adhesive power of one portion to another portion can be provided by irradiating only a portion that corresponds to a semiconductor wafer pasting portion of the pressure-sensitive adhesive layer 14 with an ultraviolet ray.

The tensile modulus at 23° C. after curing the pressure-sensitive adhesive layer 14 with an ultraviolet ray is preferably in a range of 1 to 170 MPa, and more preferably in a range of 5 to 100 MPa. By making the tensile modulus 1 MPa or more, a good pickup property can be maintained. On the other hand, by making the tensile modulus 170 MPa or less, generation of chip fly during dicing can be prevented. The radiation of the ultraviolet ray is preferably performed at an ultraviolet-ray accumulative amount of 30 to 1000 mJ/cm², for example. By making the ultraviolet-ray accumulative amount 30 mJ/cm² or more, the pressure-sensitive adhesive layer 14 can be cured sufficiently and excessive adhesion to the adhesive film 12 can be prevented. As a result, a good pickup property can be exhibited during pickup of the semiconductor chip Further, attachment of the adhesive of the pressure-sensitive adhesive layer 14 onto the adhesive film 12 (so-called adhesive residue) after pickup can be prevented. On the other hand, by making the ultraviolet-ray accumulative amount 1000 mJ/cm² or less, an excessive decrease of adhesive power of the pressure-sensitive adhesive layer 14 is prevented, and occurrence of falling off of the mounted semiconductor wafer due to peeling from the adhesive film 12 can be prevented. Further, generation of chip fly of the formed semiconductor chip can be prevented during dicing of the semiconductor wafer.

The value of the tensile modulus of the pressure-sensitive adhesive layer is obtained by the following measurement method. A sample 30.0 mm in length, 10.0 mm in width, and 0.1 to 0.5 mm² in cross sectional area was cut from the pressure-sensitive adhesive layer 14. A tensile test was performed on this sample in an MD direction at a measurement temperature of 23° C., a distance between chucks of 20 mm, a tensile speed of 50 mm/min, and the amount of change (mm) when the sample elongated was measured. The tensile modulus of the pressure-sensitive adhesive layer was obtained by drawing a tangent at the part of the initial rise in the obtained S-S (Strain-Strength) curve and dividing the tensile force when the tangent corresponded to a 100% elongation by the cross sectional area.

The adhesive film 12 is formed only on the pasting portion according to the shape at a plan view of the semiconductor wafer. Therefore, the adhesive power of the portion that corresponds to the semiconductor wafer pasting portion can be easily decreased by curing the ultraviolet-ray curing-type pressure-sensitive adhesive layer 14 in the shape of the adhesive film 12. Because the adhesive film 12 is pasted onto the portion where the adhesive power is decreased, the interface between the portion of the pressure-sensitive adhesive layer 14 and the adhesive film 12 has a characteristic of being easily peeled during pickup. On the other hand, the portion where radiation of the ultraviolet ray is not performed has a sufficient adhesive power.

As described above, the portion in which the pressure-sensitive adhesive layer 14 is formed with an uncured ultraviolet-ray curing-type pressure-sensitive adhesive adheres to the adhesive layer 12, and holding power during dicing can be maintained. In such a way, the ultraviolet-ray curing-type pressure-sensitive adhesive can support the adhesive film 12 for fixing a chip-shaped semiconductor wafer such as a semiconductor chip to an adherend such as a substrate with a good balance between adhesion and peeling. When the adhesive film 12 is laminated only on the semiconductor wafer pasting portion, a wafer ring is fixed on a region where the adhesive film 12 is not laminated.

An ultraviolet-ray curing-type pressure-sensitive adhesive having an ultraviolet-ray curable functional group such as a carbon-carbon double bond and exhibiting adherability can be used without special limitation. An example of the ultraviolet-ray curing-type pressure-sensitive adhesive is an adding type ultraviolet-ray curing-type pressure-sensitive adhesive in which ultraviolet-ray curable monomer and oligomer components are compounded into a general pressure-sensitive adhesive such as an acrylic pressure-sensitive adhesive or a rubber pressure-sensitive adhesive.

Examples of the ultraviolet curable monomer component to be compounded include such as an urethane oligomer, urethane(meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butane diol di(meth)acrylate. Further, the ultraviolet curable oligomer component includes various types of oligomers such as an urethane based, a polyether based, a polyester based, a polycarbonate based, and a polybutadiene based oligomer, and its molecular weight is appropriately in a range of about 100 to 30,000. The compounding amount of the ultraviolet ray curable monomer component and the oligomer component can be appropriately determined to an amount in which the adhesive strength of the pressure-sensitive adhesive layer can be decreased depending on the type of the pressure-sensitive adhesive layer. Generally, it is for example 5 to 500 parts by weight, and preferably about 40 to 150 parts by weight based on 100 parts by weight of the base polymer such as an acryl polymer constituting the pressure sensitive adhesive.

Further, besides the added type ultraviolet curable pressure sensitive adhesive described above, the ultraviolet curable pressure sensitive adhesive includes an internal ultraviolet curable pressure sensitive adhesive using an acryl polymer having a radical reactive carbon-carbon double bond in the polymer side chain, in the main chain, or at the end of the main chain as the base polymer. The internal ultraviolet curable pressure sensitive adhesives of an internally provided type are preferable because they do not have to contain the oligomer component, etc. that is a low molecular weight component, or most of them do not contain, they can form a pressure-sensitive adhesive layer having a stable layer structure without migrating the oligomer component, etc. in the pressure sensitive adhesive over time.

The above-mentioned base polymer, which has a carbon-carbon double bond, may be any polymer that has a carbon-carbon double bond and further has viscosity. As such a base polymer, a polymer having an acrylic polymer as a basic skeleton is preferable. Examples of the basic skeleton of the acrylic polymer include the acrylic polymers exemplified above.

The method for introducing a carbon-carbon double bond into any one of the above-mentioned acrylic polymers is not particularly limited, and may be selected from various methods. The introduction of the carbon-carbon double bond into a side chain of the polymer is easier in molecule design. The method is, for example, a method of copolymerizing a monomer having a functional group with an acrylic polymer, and then causing the resultant to condensation-react or addition-react with a compound having a functional group reactive with the above-mentioned functional group and a carbon-carbon double bond while keeping the radial ray curability of the carbon-carbon double bond.

Examples of the combination of these functional groups include a carboxylic acid group and an epoxy group; a carboxylic acid group and an aziridine group; and a hydroxyl group and an isocyanate group. Of these combinations, the combination of a hydroxyl group and an isocyanate group is preferable from the viewpoint of the easiness of reaction tracing. If the above-mentioned acrylic polymer, which has a carbon-carbon double bond, can be produced by the combination of these functional groups, each of the functional groups may be present on any one of the acrylic polymer and the above-mentioned compound. It is preferable for the above-mentioned preferable combination that the acrylic polymer has the hydroxyl group and the above-mentioned compound has the isocyanate group. Examples of the isocyanate compound in this case, which has a carbon-carbon double bond, include methacryloyl isocyanate, 2-methacryloyloxyethyl isocyanate, and m-isopropenyl-α,α-dimethylbenzyl isocyanate. The used acrylic polymer may be an acrylic polymer copolymerized with anyone of the hydroxyl-containing monomers exemplified above, or an ether compound such as 2-hydroxyethyl vinyl ether, 4-hydroxybutyl vinyl ether or diethylene glycol monovinyl ether.

The intrinsic type radial ray curable adhesive may be made only of the above-mentioned base polymer (in particular, the acrylic polymer), which has a carbon-carbon double bond. However, the above-mentioned radial ray curable monomer component or oligomer component may be incorporated into the base polymer to such an extent that properties of the adhesive are not deteriorated. The amount of the radial ray curable oligomer component or the like is usually 30 parts or less by weight, preferably from 0 to 10 parts by weight for 100 parts by weight of the base polymer.

In the case that the radial ray curable adhesive is cured with ultraviolet rays or the like, a photopolymerization initiator is incorporated into the adhesive. Examples of the photopolymerization initiator include α-ketol compounds such as 4-(2-hydroxyethoxy)phenyl(2-hydroxy-2-propyl)ketone, α-hydroxy-α,α′-dimethylacetophenone, 2-methyl-2-hydroxypropiophenone, and 1-hydroxycyclohexyl phenyl ketone; acetophenone compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether compounds such as benzoin ethyl ether, benzoin isopropyl ether, and anisoin methyl ether; ketal compounds such as benzyl dimethyl ketal; aromatic sulfonyl chloride compounds such as 2-naphthalenesulfonyl chloride; optically active oxime compounds such as 1-phenone-1,1-propanedione-2-(o-ethoxycarbonyl)oxime; benzophenone compounds such as benzophenone, benzoylbenzoic acid, and 3,3′-dimethyl-4-methoxybenzophenone; thioxanthone compound such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acylphosphonoxides; and acylphosphonates. The amount of the photopolymerization initiator to be blended is, for example, from about 0.05 to 20 parts by weight for 100 parts by weight of the acrylic polymer or the like which constitutes the adhesive as a base polymer.

The ultraviolet curing-type pressure-sensitive adhesive layer 14 can contain a compound that colors by irradiation with an ultraviolet as necessary. By containing the compound that colors by irradiation with an ultraviolet in the pressure-sensitive adhesive layer 14, only the portion irradiated with an ultraviolet can be colored. Accordingly, whether the pressure-sensitive adhesive layer 14 is irradiated with an ultraviolet or not can be visually determined immediately, and the semiconductor wafer pasting portion can be recognized easily, and the pasting of the semiconductor wafer is easy. Further, when detecting a semiconductor chip with a photosensor or the like, the detection accuracy improves, and no incorrect operation occurs during pickup of the semiconductor chip.

The compound that colors by irradiation with an ultraviolet is colorless or has a pale color before the irradiation with an ultraviolet. However, it is colored by irradiation with an ultraviolet. A preferred specific example of the compound is a leuco dye. Common leuco dyes such as triphenylmethane, fluoran, phenothiazine, auramine, and spiropyran can be preferably used. Specific examples thereof include 3-[N-(p-tolylamino)]-7-anilinofluoran, 3-[N-(p-tolyl)-N-methylamino]-7-anilinofluoran, 3-[N-(p-tolyl)-N-ethylamino]-7-anilinofluoran, 3-diethylamino-6-methyl-7-anilinofluoran, crystal violet lactone, 4,4′,4″-trisdimethylaminotriphenylmethanol, and 4,4′,4″-trisdimethylaminotriphenylmethane.

Examples of a developer that is preferably used with these leuco dyes include a prepolymer of a conventionally known phenolformalin resin, an aromatic carboxylic acid derivative, and an electron acceptor such as activated white earth, and various publicly known color developers can be used in combination for changing the color tone.

The compound that colors by irradiation with an ultraviolet may be included in the ultraviolet curing-type pressure-sensitive adhesive after it is dissolved in an organic solvent or the like, or may be included in the pressure-sensitive adhesive in the form of a fine powder. The ratio of use of this compound is 10% by weight or less, preferably 0.01 to 10% by weight, and more preferably 0.5 to 5% by weight in the pressure-sensitive adhesive layer 14. When the ratio of the compound exceeds 10% by weight, the curing of the portion of the pressure-sensitive adhesive layer 14 that corresponds to the semiconductor wafer pasting portion becomes insufficient because the ultraviolet that is radiated onto the pressure-sensitive adhesive layer 14 is absorbed too much by this compound, and the adhesive power may not decrease sufficiently. On the other hand, the ratio of the compound is preferably 0.01% by weight or more to color the compound sufficiently.

Further, when forming the pressure-sensitive adhesive layer 14 with the ultraviolet curing-type pressure-sensitive adhesive, the portion having a reduced adhesive power can be formed by using the base material 13 in which the entirety or part of the portion other than the portion corresponding to the semiconductor wafer pasting portion is protected from light, forming the ultraviolet curing-type pressure-sensitive adhesive layer 14 on this surface, and curing the portion corresponding to the semiconductor wafer pasting portion by irradiation with an ultraviolet. As a light-shielding material, a material that is capable of serving as a photo mask on a supporting film can be produced by printing, vapor deposition, or the like. According to such a manufacturing method, the film for a semiconductor device 10 of the present invention can be efficiently manufactured.

Moreover, when curing inhibition due to oxygen occurs during irradiation with an ultraviolet, it is desirable to shield oxygen (air) from the surface of the ultraviolet curing-type pressure-sensitive adhesive layer 14 in some way. Examples of the method include a method of covering the surface of the pressure-sensitive adhesive layer 14 with a separator and a method of performing irradiation with an ultraviolet in a nitrogen gas atmosphere.

The thickness of the pressure-sensitive adhesive layer 14 is not especially limited. However, it is preferably about 1 to 50 μm from the viewpoint of satisfying both of prevention of cracking on the cut surface of the chip and maintenance of the fixing of the adhesive film. It is more preferably 2 to 30 μm, and further preferably 5 to 25 μm.

The adhesive film 12 is a layer having an adhesive function, and a thermoplastic resin and a thermosetting resin may be used together or a thermoplastic resin may be used alone as its constituent.

The tensile storage modulus Ea of the adhesive film 12 is preferably in a range of 5 to 5000 MPa, more preferably in a range of 100 to 3000 MPa, and further preferably in a range of 300 to 2000 MPa. By making the tensile storage modulus Ea of the adhesive film 12 be 5 MPa or more, generation of the transfer mark on the adhesive film 12 can be more certainly suppressed. Further, the slip property of the adhesive film 12 is improved, and generation of wrinkles during pasting to the cover film 2 can be more certainly suppressed. By making the tensile storage modulus Ea of the adhesive film 12 5000 MPa or less, good adhesion to the semiconductor wafer to be mounted, a substrate to be die bonded, etc. can be obtained.

In the present invention, when the adhesive film is of a thermosetting type, the tensile storage modulus Ea of the adhesive film refers to the tensile storage modulus before thermal curing.

The value of the tensile storage modulus is obtained by the following measurement method. The adhesive film 12 having a thickness of 100 μm is formed by applying a solution of the adhesive composition onto a peeling liner subjected to a releasing treatment and drying the solution. The tensile storage modulus of the adhesive film 12 at 23° C. before curing is measured using a viscoelasticity measurement apparatus (RSA II manufactured by Rheometric Scientific FE, Ltd.). In more detail, a measurement sample having a size of 30.0 mm in length×5.0 mm in width×0.1 mm in thickness is set in a jig for measurement of film tension, and the measurement is performed in a temperature range of −30 to 280° C. under a condition of a frequency of 1.0 Hz, a strain of 0.025%, and a temperature rise rate of 10° C./min.

The weight average molecular weight of the thermoplastic resin is preferably 300,000 or more and 1,500,000 or less, more preferably 350,000 to 1,000,000, and further preferably 400,000 to 800,000. By making the weight average molecular weight of the thermoplastic resin 300,000 or more, the tensile storage modulus Ea of the adhesive film at 23° C. can be controlled to a preferred value. When the weight average molecular weight of the thermoplastic resin is 300,000 or more and the content of substances having a relatively low molecular weight is small, contamination to a clean adherend can be prevented. The weight average molecular weight is measured by GPC (Gel Permeation Chromatography), and refers to a value calculated by polystyrene conversion.

Examples of the thermoplastic resin include natural rubber, butyl rubber, isoprene rubber, chloroprene rubber, ethylene/vinyl acetate copolymer, ethylene/acrylic acid copolymer, ethylene/acrylic ester copolymer, polybutadiene resin, polycarbonate resin, thermoplastic polyimide resin, polyamide resins such as 6-nylon and 6,6-nylon, phenoxy resin, acrylic resin, saturated polyester resins such as PET and PBT, polyamideimide resin, and fluorine-contained resin. These thermoplastic resins may be used alone or in combination of two or more thereof. Of these thermoplastic resins, acrylic resin is particularly preferable since the resin contains ionic impurities in only a small amount and has a high heat resistance so as to make it possible to ensure the reliability of the semiconductor element.

The acrylic resin is not limited to any especial kind, and may be, for example, a polymer comprising, as a component or components, one or more esters of acrylic acid or methacrylic acid having a linear or branched alkyl group having 30 or less carbon atoms, in particular, 4 to 18 carbon atoms. Examples of the alkyl group include methyl, ethyl, propyl, isopropyl, n-butyl, t-butyl, isobutyl, amyl, isoamyl, hexyl, heptyl, cyclohexyl, 2-ethylhexyl, octyl, isooctyl, nonyl, isononyl, decyl, isodecyl, undecyl, lauryl, tridecyl, tetradecyl, stearyl, octadecyl, and dodecyl groups.

The glass transition temperature of the acrylic resin is preferably 20° C. or less, more preferably −20 to 15° C., and further preferably −10 to 10° C. By making the glass transition temperature of the acrylic resin −20° C. or more, the tackiness of the adhesive film 12 at the B-stage is prevented from becoming large, and good handling properties can be maintained. Further, a phenomenon that a part of the dicing film 11 melts and the pressure-sensitive adhesive attaches to the semiconductor chips during dicing can be prevented. As a result, a good pickup property of the semiconductor chips can be maintained. On the other hand, by making the glass transition temperature of the acrylic resin 20° C. or less, a decrease of the fluidity of the adhesive film 12 can be prevented. Good tackiness to the semiconductor wafer can also be maintained.

Examples of an acrylic resin having a glass transition temperature of 20° C. or less include Paracron W-197C (glass transition temperature: 18° C.) manufactured by Negami Chemical Industries Co., Ltd., and SG-708-6 (glass transition temperature: 6° C.), WS-023 (glass transition temperature: −5° C.), SG-80H (glass transition temperature: 7.5° C.), and SG-P3 (glass transition temperature: 15° C.) manufactured by Nagase ChemteX Corporation. The glass transition temperature of the acrylic resin can be obtained from the temperature of the maximum heat absorption peak measured by a differential scanning calorimeter (DSC). Specifically, using a differential scanning calorimeter (Q-2000 manufactured by TA Instruments), the glass transition temperature is measured by performing a pre-treatment by heating the measurement sample for 10 minutes at a temperature about 50° C. higher than the glass transition temperature (an estimated temperature) of the sample and then cooling the sample to a temperature 50° C. lower than the estimated temperature, increasing the temperature at a temperature rise rate of 5° C./min under a nitrogen gas atmosphere, and measuring the temperature of a heat absorption starting point.

A different monomer which constitutes the above-mentioned polymer is not limited to any especial kind, and examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl) methylacrylate; monomers which contain a sulfonic acid group, such as styrenesulfonic acid, allylsulfonic acid, 2-(meth) acrylamide-2-methylpropanesulfonic acid, (meth)acrylamidepropane sulfonic acid, sulfopropyl (meth) acrylate, and (meth) acryloyloxynaphthalenesulfonic acid; and monomers which contain a phosphoric acid group, such as 2-hydroxyethylacryloyl phosphate. Among these, a carboxyl group-containing monomer is preferable from the viewpoint that the tensile storage modulus Ea of the die bond film can be set at a preferred value.

Examples of the above-mentioned thermosetting resin include phenol resin, amino resin, unsaturated polyester resin, epoxy resin, polyurethane resin, silicone resin, and thermosetting polyimide resin. These resins may be used alone or in combination of two or more thereof. Particularly preferable is epoxy resin, which contains ionic impurities which corrode semiconductor elements in only a small amount. As the curing agent of the epoxy resin, phenol resin is preferable.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly (p-oxystyrene). These may be used alone or in combination of two or more thereof. Among these phenol resins, phenol Novolak resin and phenol aralkyl resin are particularly preferable, since the connection reliability of the semiconductor device can be improved.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

In the present embodiment, an adhesive film 12 containing an epoxy resin, a phenol resin, and an acrylic resin is especially preferable. Reliability of the semiconductor chip can be secured because these resins have fewer ionic impurities and high heat resistance. The compounding ratio is 10 to 200 parts by weight of the mixed amount of the epoxy resin and the phenol resin to 100 parts by weight of the acrylic resin component.

A thermosetting catalyst may be used in the adhesive film 12 as a constituting material of the adhesive film 12 as necessary. The compounding ratio of the catalyst to 100 parts by weight of the organic component is preferably in a range of 0.1 to 3.0 parts by weight, more preferably in a range of 0.15 to 2.0 parts by weight, and especially preferably in a range of 0.2 to 1.0 parts by weight. By making the compounding ratio 0.1 parts by weight or more, a good adhering strength after thermal curing can be exhibited. On the other hand, by making the compounding ratio 3.0 parts by weight or less, a decrease of preservability can be suppressed.

The thermosetting catalyst is not especially limited, and examples thereof include an imidazole compound, a triphenylphosphine compound, an amine compound, a triphenylborane compound, and a trihalogenborane compound. These can be used alone or two types or more can be used together.

Examples of the imidazole compound include 2-methylimidazole (trade name; 2MZ), 2-undecylimidazole (trade name: C11Z), 2-heptadecylimidazole (trade name: C17Z), 1,2-dimethylimidazole (trade name: 1.2DMZ), 2-ethyl-4-methylimidazole (trade name: 2E4MZ), 2-phenylimidazole (trade name: 2PZ), 2-phenyl-4-methylimidazole (trade name: 2P4MZ), 1-benzyl-2-methylimidazole (trade name: 1B2MZ), 1-benzyl-2-phenylimidazole (trade name: 1B2PZ), 1-cyanoethyl-2-methylimidazole (trade name: 2MZ-CN), 1-cyanoethyl-2-undecylimidazole (trade name: C11Z-CN), 1-cyanoethyl-2-phenylimidazolium trimellitate (trade name: 2PZCNS-PW), 2,4-diamino-6-[2′-methylimidazolyl-(1′)]-ethyl-s-triazine (trade name: 2MZ-A), 2,4-diamino-6-[2′-undecylimidazolyl-(1′)]-ethyl-s-triazine (trade name: C11Z-A), 2,4-diamino-6-[2′-ethyl-4′-methylimidazolyl-(1′)]-ethyl-s-triazine (trade name: 2E4MZ-A), 2,4-diamino-6-[2′-methylimidazolyl-(1′)]-ethyl-s-triazineis ocyanuric acid adduct (trade name: 2MA-OK), 2-phenyl-4,5-dihydroxymethylimidazole (trade name: 2PHZ-PW), and 2-phenyl-4-methyl-5-hydroxymethylimidazole (trade name: 2P4 MHZ-PW) (all are manufactured by Shikoku Chemicals Corporation).

The a triphenylphosphine compound is not particularly limited and includes, for example, triorganophosphines such as triphenylphosphine, tributylphosphine, tri(p-methylphenyl)phosphine, tri(nonylphenyl)phosphine and diphenyltolylphosphine, tetraphenylphosphonium bromide (TPP-PB), methyltriphenylphosphonium (trade name; TPP-MB), methyltriphenylphosphonium chloride (trade name; TPP-MC), methoxymethyltriphenylphosphonium (trade name; TPP-MOC) and benzyltriphenylphosphonium chloride (trade name; TPP-ZC) (all of which are manufactured by HOKKO CHEMICAL INDUSTRY CO., LTD.). The triphenylphosphine compound is preferably substantially insoluble in the epoxy resin. When the thermosetting catalyst is insoluble in the epoxy resin, it is possible to suppress thermal setting from excessively proceeding. The thermosetting catalyst which has a triphenylphosphine structure and also substantially exhibits insolubility in the epoxy resin includes, for example, methyltriphenylphosphonium (trade name; TPP-MB). The “insolubility” means that the thermosetting catalyst composed of the triphenylphosphine compound is insoluble in a solvent composed of an epoxy resin, and more specifically means that 10% by weight or more of the thermosetting catalyst does not dissolve at the temperature within a range from 10 to 40° C.

The triphenylborane compound is not particularly limited and further includes, for example, tri(p-methylphenyl)phosphine. The triphenylborane compound includes those having also a triphenylphosphine structure. The compound having a triphenylphosphine structure and a triphenylborane structure is not particularly limited and includes tetraphenylphosphonium tetraphenylborate (trade name; TPP-K), tetraphenylphosphonium tetra-p-triborate (trade name; TPP-MK), benzyltriphenylphosphonium tetraphenylborate (trade name; TPP-ZK) and triphenylphosphine triphenylborane (trade name; TPP-S) (all of which are manufactured by HOKKO CHEMICAL INDUSTRY CO., LTD.).

The amine compound is not particularly limited and includes, for example, monoethanolamine trifluoroborate (manufactured by Stella Chemifa Corporation) and dicyandiamide (manufactured by NACALAI TESQUE, INC.).

The trihalogenborane compound is not especially limited, and examples thereof include trichloroborane.

A multifunctional compound that reacts with a functional group at the ends of a molecular chain of a polymer may be added as a crosslinking agent to the adhesive film 12 according to this embodiment during manufacture to crosslink to some degree in advance. With this operation, the tackiness at high temperature is improved, and the heat resistance can be improved.

The crosslinking agent may be one known in the prior art. Particularly preferable are polyisocyanate compounds, such as tolylene diisocyanate, diphenylmethane diisocyanate, p-phenylene diisocyanate, 1,5-naphthalene diisocyanate, and adducts of polyhydric alcohol and diisocyanate. The amount of the crosslinking agent to be added is preferably set to 0.05 to 7 parts by weight for 100 parts by weight of the above-mentioned polymer. If the amount of the crosslinking agent to be added is more than 7 parts by weight, the adhesive force is unfavorably lowered. On the other hand, if the adding amount is less than 0.05 part by weight, the cohesive force is unfavorably insufficient. A different polyfunctional compound, such as an epoxy resin, together with the polyisocyanate compound may be incorporated if necessary.

An inorganic filler may be appropriately incorporated into the adhesive film 12 of the present invention in accordance with the use purpose thereof. The incorporation of the inorganic filler makes it possible to confer electric conductance to the sheet, improve the thermal conductivity thereof, and adjust the elasticity. Examples of the inorganic fillers include various inorganic powders made of the following: a ceramic such as silica, clay, plaster, calcium carbonate, barium sulfate, aluminum oxide, beryllium oxide, silicon carbide or silicon nitride; a metal such as aluminum, copper, silver, gold, nickel, chromium, lead, tin, zinc, palladium or solder, or an alloy thereof; and carbon. These may be used alone or in combination of two or more thereof. Among these, silica, in particular fused silica is preferably used. The average particle size of the inorganic filler is preferably from 0.01 to 80 μm.

The compounded amount of the inorganic filler is preferably set to 0 to 80 parts by weight, more preferably 0 to 70 parts by weight to 100 parts by weight of the organic component.

If necessary, other additives may be incorporated into the adhesive film 12. Examples thereof include a flame retardant, a silane coupling agent, and an ion trapping agent. Examples of the flame retardant include antimony trioxide, antimony pentaoxide, and brominated epoxy resin. These may be used alone or in combination of two or more thereof. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof. Examples of the ion trapping agent include hydrotalcite and bismuth hydroxide. These may be used alone or in combination of two or more thereof.

The thickness of the adhesive film 12 is not particularly limited, and is, for example, from about 5 to 100 μm, preferably from about 5 to 70 μm.

The film for a semiconductor device 10 can have an antistatic function. By having an antistatic function, generation of static electricity at the adhesion and peeling of the film is prevented, and the circuit is prevented from being destroyed due to charging of the semiconductor wafer, and the like. The antistatic function can be given by an appropriate method such as a method of adding an antistatic agent or a conductive substance to the base material 13, the pressure-sensitive adhesive layer 14, or the adhesive film 12 or a method of providing a conductive layer made of a complex that transfers charge to the base material 13 or a metal film. Preferred is a method by which impurity ions that can deteriorate a semiconductor wafer are hardly generated. Examples of the conductive substance (conductive filler) that is compounded to give conductivity or to improve the heat conductivity include spherical, needle-shaped, and flake-shaped metal powders of silver, aluminum, gold, copper, nickel, conductive alloys, and the like, metal oxides of alumina and the like, amorphous carbon black, and graphite. However, the adhesive film 12 is preferably non-conductive in respect that electrical leaks can be prevented.

The adhesive film 12 is protected by the cover film 2. The cover film 2 has a function as a protective material to protect the adhesive film 12 until it is used. The cover film 2 is peeled when the semiconductor wafer is pasted onto the adhesive film 12 of the adhesive film with a dicing sheet. Examples of the cover film 2 that can be used include a polyethylene terephthalate (PET) film, a polyethylene film, a polypropylene film, a plastic film whose surface is coated with a peeling agent such as a fluorine peeling agent or a long chain alkylacrylate peeling agent, and paper.

The tensile storage modulus Eb of the cover film 2 is preferably in a range of 5 to 5000 MPa, more preferably in a range of 50 to 4500 MPa, and further preferably in a range of 100 to 4000 MPa. By making the tensile storage modulus Eb of the cover film 2 be 5 MPa or more, the follow-up property of the cover film 2 to the adhesive film 12 can be improved. By making the tensile storage modulus Eb of the cover film 2 be 5000 MPa or less, generation of creases on the cover film 12 when the adhesive film 12 is pasted to the cover film 2 can be suppressed, damage to the adhesive film 12 can be prevented, and entry of air bubbles in between the films can be prevented.

The thickness of the cover film 2 is preferably 10 to 100 μm, more preferably 15 to 75 μm, and further preferably 25 to 50 μm from the viewpoints of workability and transportation property.

Next, a method of manufacturing the film 10 for a semiconductor device according to the present embodiment is explained below.

The method of manufacturing the film 10 for a semiconductor device according to the present embodiment includes a step of producing the dicing film 11 by forming the pressure-sensitive adhesive layer 14 onto the substrate 13, a step of forming the adhesive film 12 onto a base separator 22, a step of punching the adhesive film 12 into a shape of a semiconductor wafer where the film is to be pasted, a step of laminating the pressure-sensitive adhesive layer 14 of the dicing film 11 and the adhesive film 12 as a pasting surface, a step of punching the dicing film 11 into a circular shape that corresponds to a ring frame, a step of producing the adhesive film 1 with a dicing sheet by peeling the base separator 22 from the adhesive film 12, and a step of pasting the adhesive film 1 with a dicing sheet on the cover film 2 leaving a prescribed spacing.

The step of producing the dicing film 11 is performed as follows, for example. First, the base material 13 can be formed by a conventionally known film-forming method. The film-forming method includes, for example, a calendar film-forming method, a casting method in an organic solvent, an inflation extrusion method in a closed system, a T-die extrusion method, a co-extrusion method, and a dry lamination method.

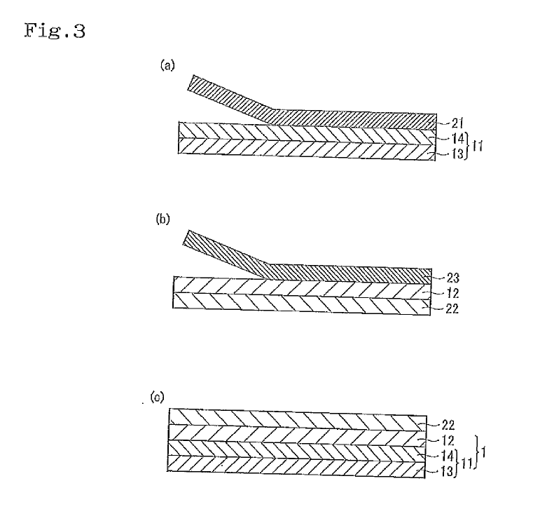

Next, a pressure-sensitive adhesive composition solution is applied on the base material 13 to form a coated film and the coated film is dried under predetermined conditions (optionally crosslinked with heating) to form the pressure-sensitive adhesive layer 14. Examples of the application method include, but are not limited to, roll coating, screen coating and gravure coating methods. The drying condition is appropriately set according to the thickness and the material of the coating film. The drying is performed at a drying temperature of 80 to 150° C. and a drying time of 0.5 to 5 minutes, for example. The pressure-sensitive adhesive layer 14 may be formed by applying a pressure-sensitive adhesive composition onto a first separator 21 to form a coating film and then drying the coating film under the above-described drying condition. After that, the pressure-sensitive adhesive layer 14 is pasted onto the base material 13 together with the first separator 21. With this operation, the dicing film 11 is produced in which the pressure-sensitive adhesive layer 14 is protected by the first separator 21 (refer to FIG. 3(a)). The produced dicing film 11 may have a long rolled shape in which the film is wound up. In this case, it is preferable to wind the film while applying a tensile force in the longitudinal direction or the width direction so that sagging, displacement of winding, and positional shift do not occur in the dicing film 11. However, the dicing film 11 is wound up in a rolled shape in a state that tensile residual strain is remained due to application of the tensile force. There is a case where the dicing film 11 is stretched due to application of the tensile force during winding of the dicing film 11. However, the winding is not intended for stretching.

When a layer made from an ultraviolet curing-type pressure-sensitive adhesive that is cured by an ultraviolet in advance is adopted as the pressure-sensitive adhesive layer 14, the layer is formed as follows. That is, the pressure-sensitive adhesive layer is formed by forming a coating film by applying an ultraviolet curing-type pressure-sensitive adhesive composition onto the base material 13 and then drying the coating film (crosslinking by heating as necessary) under a prescribed condition. The coating method, the coating condition, and the drying condition can be the same as above. Further, the pressure-sensitive adhesive layer may be formed by forming a coating film by applying the ultraviolet curing-type pressure-sensitive adhesive composition onto the first separator 21 and then drying the coating film under the above-described drying condition. After that, the pressure-sensitive adhesive layer is transferred onto the base material 13. Further, the pressure-sensitive adhesive layer is irradiated with an ultraviolet under a prescribed condition. The irradiation condition of the ultraviolet is not especially limited. However, the ultraviolet accumulative amount is normally preferably within a range of 50 to 800 mJ/cm², and more preferably within a range of 100 to 500 mJ/cm². By adjusting the ultraviolet accumulative amount to be in this range, the peel force F₂ between the adhesive film 12 and the dicing film 11 can be controlled to be within a range of 0.08 to 10 N/100 mm. When the ultraviolet accumulative amount is less than 30 mJ/cm², the curing of the pressure-sensitive adhesive layer 14 becomes insufficient, and there is a case where the peel force from the adhesive film 12 becomes too large. As a result, the adhesion with the adhesive film increases and the pickup property deteriorates. Further, there is a case where adhesive residue is generated on the adhesive film. On the other hand, when the ultraviolet accumulative amount exceeds 1000 mJ/cm², there is a case where the peel force from the adhesive film 12 becomes too small. As a result, there is a case where the interface delamination occurs between the pressure-sensitive adhesive layer 14 and the adhesive film 12. As a result, there is a case where chip fly occurs during dicing of the semiconductor wafer. Further, there is a case where the base material 13 is thermally damaged. Further, the curing of the pressure-sensitive adhesive layer 14 proceeds excessively and the tensile modulus becomes too large and as a result, the expanding property deteriorates. The irradiation with an ultraviolet may be performed after the pasting step with the adhesive film that is described later. In this case, the irradiation with an ultraviolet is preferably performed from the side of the base material 13.

The step of producing the adhesive film 12 is performed as follows. That is, a coating film is formed by applying the adhesive composition solution for forming the adhesive film 12 onto the base material separator 22 so that a prescribed thickness can be achieved. After that, the adhesive film 12 is formed by drying the coating film under a prescribed condition. The coating method is not especially limited, and examples thereof include roll coating, screen coating, and gravure coating. The drying condition is appropriately set according to the thickness, the material, and the like of the coating film. Specifically, the drying is performed at a drying temperature of 70 to 160° C. and a drying time of 1 to 5 minutes. Further, the adhesive film 12 may be formed by forming a coating film by applying the pressure-sensitive adhesive composition onto a second separator 23 and then drying the coating film under the above-described drying condition. After that, the adhesive film 12 is pasted onto the base material separator 22 together with the second separator 23. With this operation, a laminated film is produced in which the adhesive film 12 and the second separator 23 are sequentially laminated on the base material separator 23 (refer to FIG. 3(b)). The laminated film may have a long shape as a roll. In this case, it is preferable to wind the film while applying a tensile force in the longitudinal direction or the width direction so that sagging, displacement of winding, and positional shift do not occur in the adhesive film 12.

Next, the adhesive film 12 is punched into a shape of a semiconductor wafer where the film is to be pasted, and pasted to the dicing film 11. With this operation, the adhesive film 1 with a dicing sheet can be obtained. A first separator 21 is peeled from the dicing film 11 and a second separator 23 is peeled from the punched adhesive film 12, and then both of the films are pasted together so that the adhesive film 12 and the pressure-sensitive adhesive layer 14 serve as the pasting surface (refer to FIG. 3C). At this time, the pressure-bonding is performed on at least one of the dicing film 11 and the adhesive film 12 while applying a tensile force to the peripheral part of the film. When the dicing film 11 has a long rolled shape in which the film is wound up, it is preferable to transport the dicing film 11 without applying a tensile force in the longitudinal direction as much as possible. This is to suppress the tensile residual strain of the film. However, the tensile force may be applied within a range of 10 to 25 N from the viewpoint of preventing sagging, displacement of winding, positional shift, voids (air bubbles), and the like from occurring in the dicing film 11. When the tensile force is within this range, interface delamination between the dicing film 11 and the adhesive film 12 can be prevented from occurring even when the tensile residual strain remains in the dicing film 11.

The pasting of the dicing film 11 and the adhesive film 12 can be performed by pressure-bonding, for example. At this time, the laminating temperature is not especially limited. However, it is normally preferably 30 to 80° C., more preferably 30 to 60° C., and especially preferably 30 to 50° C. The linear pressure is not especially limited. However, it is normally preferably 0.1 to 20 kgf/cm, and more preferably 1 to 10 kgf/cm. The peel force F₂ between the die bond film 12 and the dicing film 11 can be controlled within a range of 0.08 to 10 N/100 mm by pasting the dicing film 11 to the adhesive film 12 in which the glass transition temperature of the adhesive composition is within a range of −20 to 50° C. by adjusting the laminating temperature and/or the linear pressure to be in the above-described range(s). The peel force F₂ between the dicing film 11 and the adhesive film 12 can be made large by making the laminating temperature high within the above-described range, for example. The peel force F₂ can also be made large by making the linear pressure large within the above-described range.

Next, the base separator 22 on the adhesive film 12 is peeled and pasted to the cover film 2 while applying a tensile force. Then, the dicing film 11 is punched into a circular shape that corresponds to a ring frame leaving a prescribed space. With this operation, the film 10 for a semiconductor device is produced in which the adhesive film 1 with a dicing sheet that is pre-cut is laminated onto the cover film 2 leaving a prescribed spacing.

The pasting of the adhesive film 12 in the adhesive film 1 with a dicing sheet to the cover film 2 is preferably performed by pressure-bonding. At this time, the laminating temperature is not especially limited. However, it is preferably 20 to 80° C., more preferably 20 to 60° C., and especially preferably 20 to 50° C. The linear pressure is not especially limited. However, it is normally preferably 0.1 to 20 kgf/cm, and more preferably 0.2 to 10 kgf/cm. The peel force F₁ between the adhesive film 12 and the cover film 2 can be controlled within a range of 0.025 to 0.075 N/100 mm by pasting the cover film 2 to the adhesive film 12 in which the glass transition temperature of the adhesive composition is within a range of −20 to 50° C. by adjusting the laminating temperature and/or the linear pressure to be in the above-described range (s). The peel force F₁ between the adhesive film with a dicing sheet 1 and the cover film 2 can be made large by making the laminating temperature large within the above-described range, for example. Further, the peel force F₁ can also be made large by making the linear pressure large within the above-described range. It is preferable to transport the cover film 2 without applying the tensile force in the longitudinal direction as much as possible. This is to suppress the tensile residual strain on the cover film 2. However, the tensile force may be applied within a range of 10 to 25 N from the viewpoint of preventing sagging, displacement of winding, positional shift, voids (air bubbles), and the like from occurring in the cover film 2. The lifting of the cover film 2 from the adhesive film with a dicing sheet 1 can be prevented from occurring even when the tensile residual strain remains in the cover film 2.

The first separator 21 that is pasted onto the pressure-sensitive adhesive layer 14 of the dicing film 11, the base material separator 22 of the adhesive film 12, and the second separator 23 that is pasted onto the adhesive film 12 are not especially limited, and conventionally known films to which a releasing treatment has been performed can be used. Each of the first separator 21 and the second separator 23 has a function as a protective material. Further, the base material separator 22 has a function as a base material when transferring the adhesive film 12 onto the pressure-sensitive adhesive layer 14 of the dicing film 11. The material that constitutes each of these films is not especially limited, and conventionally known materials can be adopted. Specific examples thereof include a polyethylene terephthalate (PET) film, a polyethylene film, a polypropylene film, a plastic film whose surface is coated with a peeling agent such as a fluorine peeling agent or a long chain alkylacrylate peeling agent, and paper.

The adhesive film of the present invention can be used as a die bond film or a film for the backside of a flip-chip type semiconductor. The film for the backside of a flip-chip type semiconductor is used to be formed on the backside of a semiconductor element (for example, a semiconductor chip) that is flip-chip bonded onto an adherend (for example, a lead frame or various substrates such as a circuit board).

### EXAMPLES

Below, preferred examples of the present invention are explained in detail. However, materials, addition amounts, and the like described in these examples are not intended to limit the scope of the present invention, and are only examples for explanation as long as there is no description of limitation in particular. Further, “part” means “parts by weight.”

### Example 1

### Production of Pressure-Sensitive Adhesive Layer of Dicing Film

An acrylic polymer A having a weight average molecular weight of 800,000 was obtained by placing 80 parts of 2-ethylhexylacrylate (2EHA), 20 parts of 2-hydroxyethylacrylate (HEA), 0.2 parts of benzoyl peroxide, and 60 parts of toluene into a reactor having a cooling tube, a nitrogen introducing tube, a thermometer, and a stirrer and performing a polymerization treatment at 61° C. in a nitrogen gas stream for 6 hours. The molar ratio of 2EHA to HEA was 100 mol to 20 mol. The measurement of the weight average molecular weight was performed as described above. The weight average molecular weight was measured by GPC (Gel Permeation Chromatography) and calculated by polystyrene conversion.

An acrylic polymer A′ was obtained by adding 10 parts (80 mol % relative to HEA) of 2-methacryloyloxyethyl isocyanate (referred to as “MOI” in the following) into the acrylic polymer A and performing an addition reaction treatment at 50° C. for 48 hours in an air flow.

Next, a pressure-sensitive adhesive solution was produced by adding 5 parts of an isocyanate crosslinking agent (trade name “Colonate L” manufactured by Nippon Polyurethane Industry Co., Ltd.) and 3 parts of a photopolymerization initiator (trade name “Irgacure 651” manufactured by Ciba Specialty Chemicals) into 100 parts of the acrylic polymer A′.

A pressure-sensitive adhesive layer having a thickness of 10 μm was formed by applying the pressure-sensitive adhesive solution that was prepared as described above onto the surface of a PET releasing liner (a first separator) to which a silicone treatment was performed and heat-crosslinking the product at 120° C. for 2 minutes. Then, a polyolefin film having a thickness of 100 μm (a base material) was pasted onto the surface of the pressure-sensitive adhesive layer. After that, it was kept at 50° C. for 24 hours.

Next, the PET releasing liner was peeled, and only a portion (a circular shape of 200 mm in diameter) that corresponds to the semiconductor wafer pasting portion (a circular shape of 220 mm in diameter) of the pressure-sensitive adhesive layer was directly irradiated with an ultraviolet. With this operation, the dicing film according to this example was produced. The irradiation condition was as described below. The tensile modulus of the pressure-sensitive adhesive layer was measured by the method described later, and the tensile modulus was 17.1 MPa.

### <Irradiation Condition of Ultraviolet>

Ultraviolet (UV) irradiation apparatus: High pressure mercury lamp

Ultraviolet accumulative amount: 300 mJ/cm²

Output: 72 W

Irradiation intensity: 200 mW/cm²

### <Production of Adhesive Film>

In methylethylketone, 5 parts of a thermosetting catalyst (trade name: TPP-K manufactured by Hokko Chemical Industry Co., Ltd.), 200 parts of an o-cresol novolac-type epoxy resin (trade name: EOCN-1027 manufactured by Nippon Kayaku Co., Ltd.), 200 parts of a phenol resin (trade name: Milex XLC-3L manufactured by Mitsui Chemicals, Inc.), and 4000 parts of spherical silica (trade name: SO-25R manufactured by Admatechs Co., Ltd., average particle size 0.5 μm) as an inorganic filler to 100 parts of an acrylic ester copolymer (an ethylacrylate-butylacrylate-acrylonitrile-acrylic acid-hydroxyethylmethacrylate copolymer) (trade name: SG-708-6 manufactured by Nagase ChemteX Corporation, glass transition temperature: 6° C., weight average molecular weight: 800,000) as the acrylic resin were dissolved, and the concentration was adjusted to be 58.0% by weight.

A coating layer was formed by applying this adhesive composition solution onto a release treated film (base material separator) by a fountain coater, and the coating layer was dried by directly blowing the layer with hot air at 150° C. at 10 m/s for 2 minutes. With this operation, a adhesive film having a thickness of 25 μm was produced on the release treated film. A polyethylene terephthalate film (thickness 50 μm) to which a silicone release treatment had been performed was used as the release treated film.

<Production of Adhesive Film with Dicing Sheet>

Next, the adhesive film was cut into a circular shape having a diameter of 230 mm, and the pressure-sensitive adhesive layer of the dicing film and the adhesive film cut into a circular shape were pasted together. The films were pasted together using a nip roll. The pasting conditions were a lamination temperature of 50° C. and a line pressure of 3 kgf/cm. Then, a releasing treatment film (a cover film) was formed by peeling the base separator on the adhesive film, and a polyolefin film (25 μm thick) subjected to a silicone releasing treatment was pasted thereto. At this time, an adhesive film with a dicing sheet was produced by pasting the polyolefin film at a line pressure of 2 kgf/cm without applying the lamination temperature while applying a tensile force of 17 N onto the cover film in the MD direction using a dancer roll to prevent generation of positional deviation, voids (air bubbles), etc.

### <Production of Film for Semiconductor Device>

The film for a semiconductor device according to the present example was obtained from 200 adhesive films with a dicing sheet being pasted leaving a space of 10 mm by punching the dicing film into a circular shape having a diameter of 270 mm with the adhesive film as the center.

### Example 2

### Production of Dicing Film

The same dicing film as in Example 1 was used as the dicing film according to this example.

### <Production of Adhesive Film>

In methylethylketone, 1 part of an isocyanate crosslinking agent (trade name: Coronate HX manufactured by Nippon Polyurethane Industry Co., Ltd.), 400 parts of an o-cresol novolac-type epoxy resin (trade name: EOCN-1027 manufactured by Nippon Kayaku Co., Ltd.), 400 parts of a phenol resin (trade name: Milex XLC-LL manufactured by Mitsui Chemicals, Inc.), and 100 parts of spherical silica (trade name: SO-25R manufactured by Admatechs Co., Ltd., average particle size 0.5 μm) as an inorganic filler to 100 parts of an acrylic ester polymer (trade name: Paracron W-197CM manufactured by Negami Chemical Industries Co., Ltd., Tg: 18° C., weight average molecular weight: 400,000) having ethylacrylate-methylmethacrylate as a main component were dissolved, and the concentration was adjusted to be 20.0% by weight.

### <Production of Film for Semiconductor Device>

The film for a semiconductor device according to Example 2 was obtained by pasting a polyethylene terephthalate film (100 μm thick) subjected to a silicone releasing treatment in the same manner as in Example 1 except using the above-described adhesive film.

### Comparative Example 1

The film for a semiconductor device according to the present comparative example was produced in the same manner as in Example 1 except the added amount of an acrylic ester copolymer (an ethylacrylate-butylacrylate-acrylonitrile-acrylic acid-hydroxyethylmethacrylate copolymer) (trade name: SG-708-6 manufactured by Nagase ChemteX Corporation, glass transition temperature: 6° C., weight average molecular weight: 800,000) was increased by 10 parts in the production of the adhesive film.

### Comparative Example 2

The film for a semiconductor device according to the present comparative example was produced in the same manner as in Example 2 except 1 part of an isocyanate crosslinking agent (trade name: Coronate HX manufactured by Nippon Polyurethane Industry Co., Ltd.), 400 parts of an o-cresol novolac-type epoxy resin (trade name: EOCN-1027 manufactured by Nippon Kayaku Co., Ltd.), 400 parts of a phenol resin (trade name: Milex XLC-LL manufactured by Mitsui Chemicals, Inc.), and 100 parts of spherical silica (trade name: SO-25R manufactured by Admatechs Co., Ltd., average particle size 0.5 μm) as an inorganic filler to 100 parts of an acrylic ester polymer (trade name: Paracron W-197C manufactured by Negami Chemical Industries Co., Ltd., Tg: 5° C., weight average molecular weight: 280,000) having ethylacrylate-methylmethacrylate as a main component were dissolved in methylethylketone, and the concentration was adjusted to be 15.0% by weight.

### (Tensile Modulus of Pressure-Sensitive Adhesive Layer)

The value of the tensile modulus of the pressure-sensitive adhesive layer was obtained by the following measurement method. A sample 30.0 mm in length, 10.0 mm in width, and 0.1 to 0.5 mm² in cross sectional area was cut from the pressure-sensitive adhesive layer 14. A tensile test was performed on this sample in the MD direction at a measurement temperature of 23° C., a distance between chucks of 20 mm, a tensile speed of 50 mm/min, and the amount of change (mm) due to the sample's elongation was measured. The tensile modulus of the pressure-sensitive adhesive layer was obtained by drawing a tangent at the part of the initial rise in the obtained S-S (Strain-Strength) curve and dividing the tensile force when the tangent corresponded to a 100% elongation by the cross sectional area.

### (Tensile Storage Modulus Ea of Adhesive Film at 23° C.)

A dicing film was obtained by applying the adhesive composition in each example and comparative example onto a peeling liner subjected to a releasing treatment so that the thickness becomes 100 μm. The tensile modulus of the adhesive film at 23° C. was measured using a viscoelasticity measurement apparatus (type: RSA II manufactured by Rheometric Scientific FE, Ltd.). In more detail, a measurement sample having a size of 30.0 mm in length×5.0 mm in width×0.1 mm in thickness was set in a jig for measurement of film tension, and the measurement was performed in a temperature range of −30 to 280° C. under conditions of a frequency of 1.0 Hz, a strain of 0.025%, and a temperature rise rate of 10° C./min.

### (Tensile Storage Modulus Eb of Cover Film at 23° C.)

The tensile modulus of the cover film in each example and comparative example at 23° C. was measured using a viscoelasticity measurement apparatus (type: RSA II manufactured by Rheometric Scientific FE, Ltd.). In more detail, a measurement sample having a size of 30.0 mm in length×5 mm in width was set in a jig for measurement of film tension, and the measurement was performed in a temperature range of −30 to 280° C. under conditions of a frequency of 1.0 Hz, a strain of 0.025%, and a temperature rise rate of 10° C./min.

### (Measurement of Peel Force)

The measurement of the peel force between the adhesive film and the cover film and the peel force between the dicing film and the adhesive film for each of the films for a semiconductor device obtained in the examples and comparative examples was performed under conditions of a temperature of 23±2° C., a relative humidity of 55±5% Rh, and a peeling speed of 300 mm/min using a T type peeling tester (JIS K6854-3). Autograph AGS-H manufactured by Shimadzu Corporation was used as a tensile tester.

### (Existence of Interface Delamination and Film Lifting)

Film lifting in each of the films for a semiconductor device obtained in the examples and comparative examples was confirmed as follows. That is, each of the films for a semiconductor device was placed in a freezer at a temperature of −30±2° C. for 120 hours. Then, the film was placed in an environment of a temperature of 23±2° C. and a relative humidity of 55±5% Rh for 24 hours. After that, the existence of interface delamination and film lifting between the films in the film for a semiconductor device was evaluated. For the evaluation criteria, the case where interface delamination and film lifting were not visually observed was marked good, and the case where they were observed was marked poor.

(Presence or Absence of Voids after Mounting)

Presence or absence of voids in the film for the semiconductor device obtained in each example or comparative example was confirmed as follows. Each film for a semiconductor device was peeled from the cover film, and a semiconductor wafer was mounted on the adhesive film. A semiconductor wafer having a size of 8 inches and a thickness of 75 μm was used. The mounting conditions of the semiconductor wafer were as follows.

### <Pasting Conditions>

Pasting apparatus: tradename: RM-300 manufactured by ACC Co., Ltd.

Pasting speed: 20 mm/sec

Pasting pressure: 0.25 MPa

Pasting temperature: 60° C.

Next, presence or absence of voids (air bubbles) on the pasting surface of the adhesive film with a dicing sheet and the semiconductor wafer was confirmed by a microscope. The result is shown in Table 1.

### (Evaluation of Pickup)

The cover film was peeled from each film for a semiconductor device, and a semiconductor wafer was mounted on the adhesive film. A semiconductor wafer having a size of 8 inches and a thickness of 75 μm was used. The mounting conditions of the semiconductor wafer were the same as described above.

Next, dicing of the semiconductor wafer was performed according to the conditions described below, and 30 semiconductor chips were formed. The semiconductor chips were picked up together with the die bond film. The pickup was performed on 30 semiconductor chips (5 mm×5 mm) and the success rate was calculated by counting the cases in which the pickup of the semiconductor chip was successful without damage. The result is shown in Table 1. The pickup conditions were as follows.

### <Dicing Conditions>

Dicing method: step cut

Dicing apparatus: DISCO DFD6361 (trade name, manufactured by DISCO Corporation)

Dicing speed: 30 mm/sec

Dicing blade: Z1; NBC-ZH2030-SE27HDD manufactured by DISCO Corporation

Z2; NBC-ZH2030-SE27HBB manufactured by DISCO Corporation

Dicing blade rotation speed: Z1; 50,000 rpm, Z2; 50,000 rpm

Dicing tape cut depth: 25 μm

Wafer chip size: 5 mm×5 mm

### <Pickup Conditions>

Pickup apparatus: trade name SPA-300 manufactured by Shinkawa Ltd.

Number of needles: 5 needles

Needle pushing distance: 300 μm

Needle pushing speed: 10 mm/sec

Needle pulling down distance: 3 mm

<Evaluation of Presence or Absence of Voids Due to Rolling Mark Transfer after Kept in a Refrigerated Condition for One Month>

Each of the films for a semiconductor device obtained in each example or comparative example was wound up into a roll with a winding tension of 2 kg. Then, the film was kept as it is in a refrigerator at a temperature of 5° C. for one month. After that, the temperature was returned to room temperature, the film was unrolled, mounting of a semiconductor wafer was performed using a 100^{th} adhesive film with a dicing sheet, and the presence or absence of voids was confirmed visually. A semiconductor wafer having a size of 8 inches and a thickness of 75 μm was used. The pasting conditions were the same as in the void evaluation after mounting. The result is shown in Table 1.

TABLE 1

| | Exam- | Exam- | Comparative | Comparative |
|---|---|---|---|---|
| | ple 1 | ple 2 | Example 1 | Example 2 |
| Modulus Ea of Die | 4935 | 4.9 | 5406 | 3.0 |
| bond film (MPa) | | | | |
| Modulus Eb of | 105 | 3740 | 106 | 3770 |
| cover film (MPa) | | | | |
| Ea/Eb | 47 | 0.0013 | 51 | 0.0008 |
| Peeling force F₁ | 0.043 | 0.068 | 0.02 | 0.65 |
| (N/100 mm) | | | | |
| Peeling force F₂ | 0.083 | 0.68 | 0.058 | 1.4 |
| (N/100 mm) | | | | |
| Presence or absence | ◯ | ◯ | ◯ | ◯ |
| of interface | | | | |
| peeling and film | | | | |
| floating | | | | |
| Presence or absence | Absent | Absent | Present | Present |
| of voids after | | | | |
| mounting | | | | |
| Pickup success | 100 | 100 | 100 | 0 |
| rate (%) | | | | |
| Presence or absence | Absent | Absent | Present | Present |
| of voids due to | | | | |
| rolling mark | | | | |
| transfer | | | | |

In Table 1, the peeling force F₁ is the peeling force between the adhesive film with a dicing sheet and the cover film, and the peeling force F₂ is the peeling force between the dicing film and the adhesive film.

### (Result)

As is apparent from Table 1, voids were not observed right after mounting of the semiconductor wafer when the film for a semiconductor device of Example 1 or 2 was used. When the film was wound and kept in refrigeration for a month, voids due to the rolling mark transfer were not observed. Further, a good pickup property was obtained. Contrary to this, voids were observed right after mounting of the semiconductor wafer when the film for a semiconductor device of Comparative Example 1 was used. The phenomenon of floating of the cover film was also observed. Further, chip fly and chipping were generated although the pickup success rate was 100%. The voids were observed right after mounting of the semiconductor wafer when the film for a semiconductor device of Comparative Example 2 was used. When the film was wound and kept in refrigeration for a month, voids due to the rolling mark transfer were observed. Further, the phenomenon of floating of the cover film was also observed. Furthermore, pickup became difficult because of high adhesion between the dicing film and the adhesive film, and cracking and chipping of the semiconductor chip occurred.

1. A film for a semiconductor device in which an adhesive film with a dicing sheet obtained by laminating an adhesive film onto a dicing film is laminated onto a cover film leaving a prescribed spacing, wherein
a ratio Ea/Eb of the tensile storage modulus Ea of the adhesive film at 23° C. to the tensile storage modulus Eb of the cover film at 23° C. is in a range of 0.001 to 50.

2. The film for a semiconductor device according to claim 1, wherein
a peeling force F₁ between the adhesive film and the cover film obtained by a T type peeling test under conditions of a temperature of 23±2° C. and a peeling rate of 300 mm/min is in a range of 0.025 to 0.075 N/100 mm, a peeling force F₂ between the adhesive film and the dicing film obtained by a T type peeling test under conditions of a temperature of 23±2° C. and a peeling rate of 300 mm/min is in a range of 0.08 to 10 N/100 mm, and F₁ and F₂ satisfy a relationship of F₁<F₂.

3. The film for a semiconductor device according to claim 1, wherein
the adhesive film contains a thermoplastic resin having a weight average molecular weight of 300,000 or more and 1,500,000 or less.

4. The film for a semiconductor device according to claim 1, wherein
the adhesive film contains a thermoplastic resin in which monomer components having a carboxyl group-containing monomer are polymerized.

5. The film for a semiconductor device according to claim 1, wherein
the adhesive film contains an acrylic resin as a thermoplastic resin, and
the glass transition temperature of the acrylic resin is 20° C. or less.

6. The film for a semiconductor device according to claim 1, wherein
the tensile storage modulus Ea of the adhesive film at 23° C. is 5 to 5000 MPa.

7. The film for a semiconductor device according to claim 1, wherein
the tensile storage modulus Eb of the cover film at 23° C. is 5 to 5000 MPa.

8. A semiconductor device manufactured using the film for a semiconductor device according to claim 1.

9. The film for a semiconductor device according to claim 1, which is wound into a roll form.

10. A film for a semiconductor device comprising:
a cover film;
an adhesive film laminated onto the cover film; and
a dicing film laminated onto the adhesive film,
wherein a ratio Ea/Eb of the tensile storage modulus Ea of the adhesive film at 23° C. to the tensile storage modulus Eb of the cover film at 23° C. is in a range of 0.001 to 50.

11. The film for a semiconductor device according to claim 10, wherein the adhesive film and the dicing film both have a circular-shape so as to form a circular-shaped adhesive film/dicing film laminate, and wherein two or more of the circular-shaped adhesive film/dicing film laminates are laminated on the cover film.

12. A method of manufacturing a semiconductor device comprising
providing the film for a semiconductor device according to claim 1;
pasting the film for a semiconductor device onto a semiconductor wafer; and
dicing the semiconductor wafer to form diced semiconductor chips.

13. The method of claim 12, further comprising
peeling the dicing film from the adhesive film such that the adhesive film remains attached to the semiconductor chip.

14. The method of claim 13, further comprising
pasting the semiconductor chip to a substrate, a lead frame, or a semiconductor element via the adhesive film; and
bonding wires to the semiconductor chip.

15. The method of claim 12, wherein the pasting of the film for a semiconductor device onto the semiconductor wafer comprises
peeling the dicing film together with the adhesive film from the cover film as an adhesive film/dicing film laminate; and
adhering the adhesive film/dicing film laminate to the semiconductor wafer via the adhesive film.

16. A method of manufacturing a semiconductor device comprising
providing the film for a semiconductor device according to claim 10;
pasting the film for a semiconductor device onto a semiconductor wafer; and
dicing the semiconductor wafer to form diced semiconductor chips.

17. A method of manufacturing a semiconductor device comprising
providing the film for a semiconductor device according to claim 11;
pasting the film for a semiconductor device onto a semiconductor wafer; and
dicing the semiconductor wafer to form diced semiconductor chips.
